(19) United States
(12) Patent Application Publication
(10) Pub. No.: US 2012/0052785 A1
(43) Pub. Date: Mar. 1, 2012

(54) COOLING SYSTEM AND COOLING METHOD

(75) Inventors: Ikuro NAGAMATSU, Kawasaki (JP); Yuji Ohba, Kawasaki (JP); Junichi Ishimine, Kawasaki (JP)

(73) Assignee: Fujitsu Limited, Kawasaki (JP)

(21) Appl. No.: 13/212,443

(22) Filed: Aug. 18, 2011

(30) Foreign Application Priority Data
Aug. 25, 2010 (JP) 2010-188885

(51) Int. Cl. H05K 5/02

(52) U.S. Cl. 454/184

(57) ABSTRACT

A cooling system for cooling an electronic device housed in a rack disposed in a room, the cooling system includes an air conditioner includes an inlet and an outlet and being configured to suck air through the inlet, cool the sucked air, and discharge the cooled air through the outlet, a control unit configured to acquire a temperature at an intake port and an exhaust port of the rack and the inlet and the outlet of the air conditioner from a temperature measuring instrument for measuring the temperature, to calculate an index concerning an airflow rate of each of the ejected air and the cooled air directly returning, and to perform control on an airflow rate of the cooled air being discharged from the air conditioner on the basis of the calculated result.

### CROSS-REFERENCE TO RELATED APPLICATION

This application is based upon and claims the benefit of priority from the prior Japanese Patent Application No. 2010-188885 filed on Aug. 25, 2010, the entire contents of which are incorporated herein by reference.

### FIELD

The embodiments disclosed herein are related to a cooling system and a cooling method for cooling an electronic device in a room.

### BACKGROUND

A data center for supplying cooled air to an electronic device, such as a server, from under a floor through an aperture panel is available. Such a data center typically has a double floor structure with a lower floor and an upper floor, and an electronic device is disposed above the upper floor. For the data center, with increases in heat generated by the electronic device mounted on the rack and in the density thereof, the amount of heat per server rack tends to increase. This may raise the occurrence of a hot spot resulting from a flow of air in a route along which ejected air from the server rack is sucked into the server rack without passing through an air conditioner (hereinafter, such a flow of air is also referred to as ejected air directly returning). The occurrence of a hot spot may incur the risk of causing a failure in the server.

Meanwhile, to control an air conditioner to reduce the occurrence of a hot spot, the temperature of cooled air of the air conditioner tends to decrease too much or the volume of the cooled air tends to excessively increase. Accordingly, if the air conditioner is controlled so as to reduce the occurrence of a hot spot, an issue arises in that power consumption increases.

One known example approach to preventing the occurrence of a hot spot caused by ejected air directly returning is a system for determining a re-circulation index value calculated from a temperature measured at the entrance and exit for an airflow of a server rack in which an electronic device is housed and a temperature measured at the inlet and vent of air in an air conditioner and varying workload placement on the electronic device in response to the determined value. However, a technique for reducing power consumption of an air conditioner by controlling the airflow rate of air being discharged from the air conditioner while at the same time using the server with safety has not been disclosed.

The followings are reference documents.
[Document 1] Japanese National Publication of International Patent Application No. 2007-505285.

### SUMMARY

According to an aspect of the embodiment, a cooling system for cooling an electronic device housed in a rack disposed in a room in which an air conditioner is disposed, the air conditioner including an inlet and an outlet and being configured to suck air through the inlet, cool the sucked air, and discharge the cooled air through the outlet, the rack including an intake port and an exhaust port and being configured to suck the cooled air through the intake port and eject the sucked air through the exhaust port, the cooling system includes: a control unit configured to acquire a temperature at least one of the intake port and the exhaust port of the rack and the inlet and the outlet of the air conditioner from a temperature measuring instrument for measuring the temperature, to calculate an index concerning an airflow rate of each of the ejected air and the cooled air directly returning, and to perform control on an airflow rate of the cooled air being discharged from the air conditioner on the basis of the calculated result.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic diagram of a cooling system according to a first embodiment;

FIG. 2 is a schematic diagram that illustrates a flow of air inside a data center in the cooling system according to the first embodiment;

FIG. 3 illustrates a concept of a relationship between an airflow rate Qa of air passing through an air conditioner and an index A;

FIG. 4 is a flowchart of a process of a cooling method for use in the cooling system according to the first embodiment;

FIG. 5 is a flowchart of a process of a method for controlling a temperature of the air conditioner during operation of controlling the airflow rate for the air conditioner;

FIG. 6 is a block diagram of a controller of the cooling system according to the first embodiment;

FIG. 7 is a schematic diagram of a cooling system according to a second embodiment;

FIG. 8 is a flowchart of a process of an example cooling operation in the cooling system according to the second embodiment;

FIGS. 9A to 9C are schematic diagrams of an example of the cooling operation in the cooling system according to the second embodiment; and

FIGS. 10A to 10C are schematic diagrams of another example of the cooling operation in the cooling system according to the second embodiment.

### DESCRIPTION OF EMBODIMENTS

### Cooling System According to First Embodiment

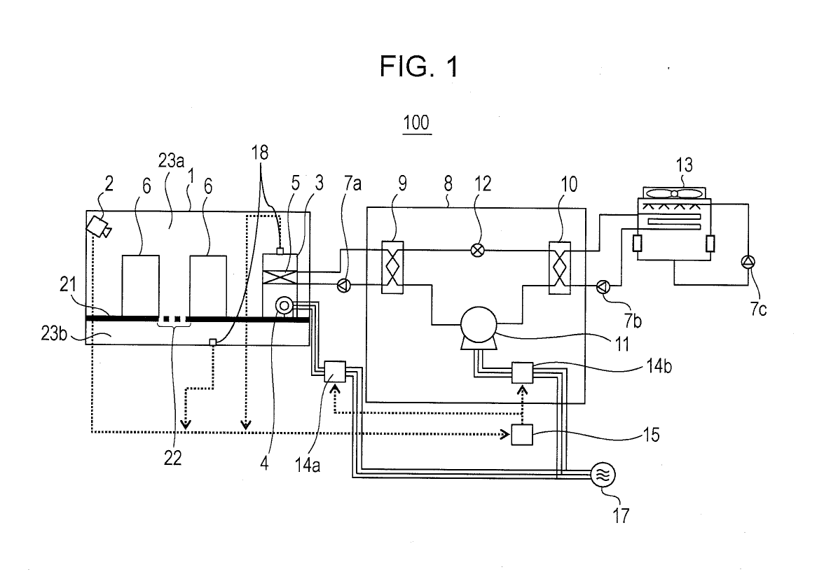

FIG. 1 is a schematic diagram of a cooling system 100 according to a first embodiment.

The cooling system 100 according to the first embodiment is a cooling system for cooling an electronic device (not illustrated) disposed in a data center 1. The data center 1 includes an air conditioner 3 and one or more racks 6 for housing an electronic device (not illustrated) above a floor 21. The data center 1 has two floor levels of an upper space 23a and a lower space 23b.

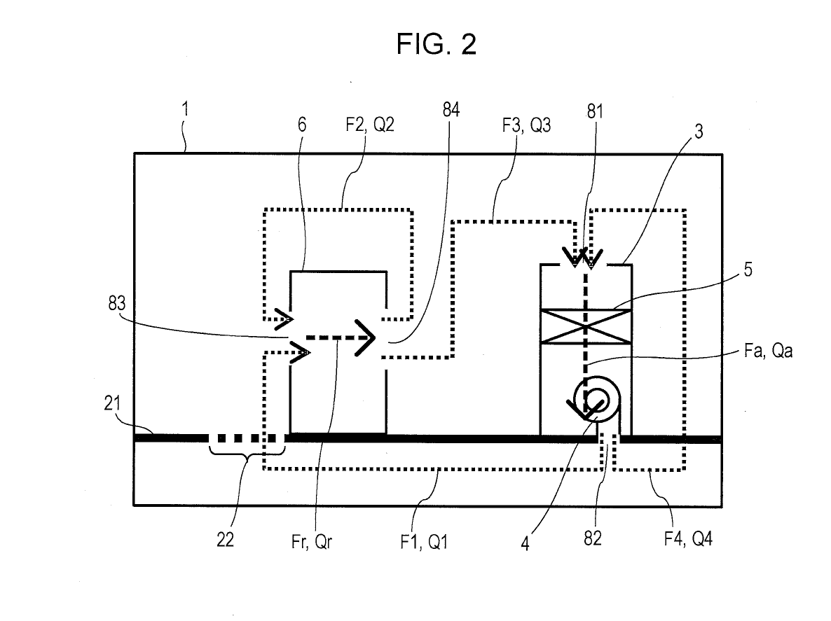

The air conditioner 3 has an inlet 81 for sucking air there through and an outlet 82 for discharging cooled air therethrough (see FIG. 2). The air conditioner 3 also has a heat exchanger 5 for cooling air sucked through the inlet 81 and a blower 4 for blowing cooled air. The air conditioner 3 may further have a fan (not illustrated) contributing to suck air through the inlet 81.

A pump 7a circulates a refrigerant between a refrigerator 8 and the heat exchanger 5, and heat drawn from air by the heat exchanger 5 is conveyed to the outside through the refrigerator 8. The refrigerator 8 may include, although not is limited to, an evaporator 9, a compressor 11, a condenser 10, and an expansion valve 12, for example. The heat conveyed from the heat exchanger 5 to the evaporator 9 is conveyed to the condenser 10 by the refrigerant circulated through the evaporator 9, compressor 11, condenser 10, and the expansion valve 12. The heat conveyed to the condenser 10 is released to the outside by the refrigerant circulated between the condenser 10 and a cooling tower 13 by pumps 7b and 7c.

The blower 4 and the compressor 11 each includes an alternating-current motor and are connected to a power source 17 through inverters 14a and 14b, respectively.

The air conditioner 3 sends cooled air toward the lower space 23b. The cooled air sent to the lower space 23b is sent from the lower space 23b to the upper space 23a through a vent 22. The sent cooled air cools an electronic device housed in each of the racks 6. The vent 22 for use in supplying cooled air to the electronic device is typically positioned in the vicinity of the electronic device to prevent the cooled air from being mixed with an ejected hot air flow ejected from the rack.

The rack 6 includes an intake port 83 for sucking cooled air from under the floor therethrough and an exhaust port 84 for ejecting air occurring in exchanging heat with an inside electronic device therethrough (see FIG. 2). The rack 6 may further have a fan (not illustrated) contributing to suck cooled air and eject the sucked air.

The data center 1 is provided with an infrared camera 2 and one or more temperature sensors 18. The infrared camera 2 and temperature sensors 18 are provided to measure a temperature within a specific range of each of the rack 6 and the air conditioner 3.

The single infrared camera 2 measures a temperature in a wide range. The range of a temperature measured by each of the temperature sensors 18 is narrower than that by the infrared camera 2. The temperature sensor 18 may be a thermocouple, for example, and is able to measure a temperature when being thermally coupled to a measurement target.

A controller 15 is connected to the infrared camera 2 and temperature sensor 18. The controller 15 calculates an index “A” concerning the airflow rate of ejected air directly returning to the rack 6 with respect to the airflow rate of the air passing through the air conditioner 3 and concerning the airflow rate of cooled air directly returning to the air conditioner 3 with respect to the airflow rate of the air passing through the air conditioner 3 on the basis of information on a temperature measured by each of the infrared camera 2 and the temperature sensor 18.

The controller 15 is connected to the inverters 14a and 14b. The controller 15 controls the airflow rate and temperature of cooled air discharged from the air conditioner 3 on the basis of the calculated index A. Specifically, the controller 15 controls the airflow rate of cooled air from the air conditioner 3 by controlling the motor frequency of the blower 4 in the inverter 14a and controls the temperature of cooled air of the air conditioner 3 by controlling the motor frequency of the compressor 11 in the inverter 14b.

FIG. 2 is a schematic diagram that illustrates a flow of air inside the data center 1 in the cooling system according to the first embodiment.

Temperature Tr,in at the intake port 83 of the rack 6, temperature Tr,out at the exhaust port 84 of the rack 6, temperature Ta,in at the inlet 81 of the air conditioner 3, and temperature Ta,out at the outlet 82 of the air conditioner 3 are detected by the use of the infrared camera 2 or temperature sensor 18 (not illustrated).

The rack 6 may have a plurality of intake ports 83 and a plurality of exhaust ports 84. The size of each of the plurality of intake ports 83 and exhaust ports 84 and their distribution in the casing of the rack 6 are not particularly limited. The temperature Tr,in may be the mean value of temperatures at the plurality of intake ports 83, and the temperature Tr,out may be the mean value of temperatures at the plurality of exhaust ports 84.

The air conditioner 3 may have a plurality of inlets 81. The size of each of the inlets 81 and their distribution in the casing of the air conditioner 3 are not particularly limited. The temperature Ta,in may be the mean value of temperatures at the plurality of inlets 81.

The representative temperature at the plurality of intake ports 83 of the rack 6 may be used as the temperature Tr,in. The representative temperature at the exhaust ports 84 of the rack 6 may be used as the temperature Tr,out. The representative temperature at the inlets 81 of the air conditioner 3 may be used as the temperature Ta,in. The representative temperature may be the maximum temperature or minimum temperature, for example.

The above-described mean temperature and the above-described representative temperature are obtainable by the controller 15 calculating the mean value using temperature data acquired from detection of temperatures at the plurality of inlets, outlets, and intake ports by the infrared camera 2 or temperature sensor 18 (not illustrated).

Airflow F1 is a flow of air in a route along which, of cooled air discharged through the outlet 82 of the air conditioner 3, air is sucked into the rack 6 through the intake port 83 of the rack 6. The airflow rate of the airflow F1 is Q1. Airflow F2 is a flow of air in a route along which, of air ejected through the exhaust port 84 of the rack 6, air is sucked into the rack 6 through the intake port 83. The airflow rate of the airflow F2 is Q2. Airflow F3 is a flow of air in a route along which, of air ejected through the exhaust port 84 of the rack 6, air is sucked into the air conditioner 3 through the inlet 81. The airflow rate of the airflow F3 is Q3. Airflow F4 is a flow of air in a route along which, of cooled air discharged through the outlet 82 of the air conditioner 3, air is sucked into the air conditioner 3 through the inlet 81. The airflow rate of the airflow F4 is Q4.

When airflows in the data center 1 are classified into the above-described four groups, the airflow F2 is a flow in which an ejected air flow from the rack 6 directly returns thereto and the airflow F4 is a flow in which discharged cooled air directly returns to the air conditioner 3 without being supplied to an electronic device inside the rack 6. Both airflows are unnecessary. Accordingly, it is useful that the airflows F2 and F4 be controlled such that both are reduced.

The index A concerning the airflow rate of ejected air directly returning to the rack and that of cooled air discharged directly returning to the air conditioner may be expressed by the following equation (1).

A=ξ·(Q2/Qa)+η·(Q4/Qa) (1)

where Qa is the airflow rate of the airflow Fa passing through the air conditioner 3, ξ and η are weighting factors, Q2/Qa is the ratio of the airflow rate Q2 of ejected air directly returning with respect to the airflow rate Qa of the air passing through the air conditioner 3, and Q4/Qa is the ratio of the airflow rate Q4 of cooled air directly returning with respect to the airflow rate Qa of the air passing through the air conditioner 3. The weighting factors ξ and η are added to the ratio Q2/Qa of the airflow rate of ejected air directly returning with respect to the airflow rate Qa and the ratio Q4/Qa of the airflow rate of cooled air directly returning with respect to the airflow rate Qa, respectively, in accordance with the shape and state of the data center 1 and a usage policy, such as the degree of safety that a user intends to operate or the intention to operate in an energy-saving manner.

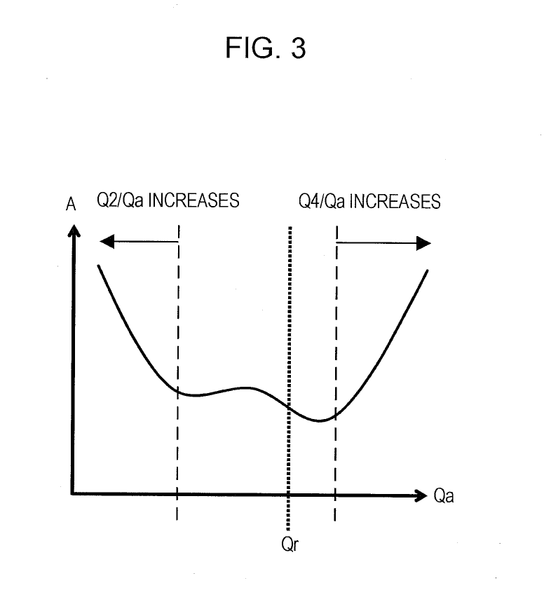

FIG. 3 illustrates a concept of a relationship between the airflow rate Qa of air passing through the air conditioner 3 and the index A. Here, the airflow rate Qr of air passing through the rack 6 is assumed to be constant. If the airflow rate Qa of the air passing through the air conditioner 3 is too high with respect to the airflow rate Qr of the air passing through the rack 6, the airflow rate Q4 of cooled air that is discharged from the air conditioner 3 and directly returns to the inlet of the air conditioner without passing through the rack 6 is increased. Thus Q4/Qa is increased, and the index A is also increased. In contrast, if the airflow rate Qa of the air passing through the air conditioner 3 is too low with respect to the airflow rate Qr of the air passing through the rack 6, the airflow rate of the air that directly returns to the inlet 81 of the air conditioner 3 from the air conditioner 3 without passing through the rack 6 is decreased, whereas the air ejected through the exhaust port 84 of the rack 6 and returning to the intake port 83 of the rack 6 is increased. Thus Q2/Qa is increased, and the index A is also increased.

Therefore, controlling the airflow rate of cooled air being discharged from the air conditioner 3 such that the index A is reduced enables an electronic device disposed in the data center 1 to be used safely with reduced power consumption.

The ratio Q2/Qa of the airflow rate of ejected air directly returning with respect to the airflow rate Qa and the ratio Q4/Qa of the airflow rate of cooled air directly returning with respect to the airflow rate Qa may be calculated from the temperatures at the intake port 83 and the exhaust port 84 of the rack 6 and at the inlet 81 and the outlet 82 of the air conditioner 3, as described below.

First, the ratio Q2/Qa of the airflow rate Q2 of ejected air directly returning to the rack with respect to the airflow rate Qa of the air passing through the air conditioner 3 is determined.

For the temperature Tr,in at the intake port 83 of the rack 6, the following equation (2) is established.

Tr,in =(Q2/Qr)·Tr,out+(Q1/Qr)·Tr,out (2)

where Qr is the airflow rate of the airflow Fr passing through the rack. That is, the temperature Tr,in at the intake port 83 of the rack 6 is the sum of the product of the temperature Tr,out at the exhaust port 84 of the rack and the ratio of the airflow rate Q2 of ejected air directly returning with respect to the airflow rate Qr of the air passing through the rack and the product of the temperature Ta,out at the outlet 82 of the air conditioner and the ratio of the airflow rate Q4 of cooled air directly returning with respect to the airflow rate Qr of the air passing through the rack.

For the airflow rate Qr of the air passing through the rack, the following equation (3) is established.

Q1+Q2=Qr (3)

From the above equations (2) and (3), the following equation (4) may be determined.

Q2/Qr=(Ta,out−Tr,in)/(Ta,out−Tr,out) (4)

The following equation (5) of conservation of energy is established.

P=ρ·Cp·Qr·(Tr,in−Tr,out)=ρ·Cp·Qa·(Ta,in−Ta,out) (5)

where P is the amount of heat generated, ρ is the density of air, and Cp is the heat capacity at constant pressure.

From the above equations (4) and (5), Q2/Qa may be determined.

$$\begin{matrix}Q 2 / Qa = ( Q 2 / Qr ) ( Qr / Qa ) \\ = \{ ( Ta , out - Tr , in ) / ( Ta , out - Tr , out ) \} \cdot \\ \{ ( Ta , in - Ta , out ) / ( Tr , in - Tr , out ) \}\end{matrix} \qquad ( 6 )$$

Next, the ratio Q4/Qa, which is the ratio of the airflow rate Q4 of cooled air directly returning to the air conditioner 3 with respect to the airflow rate Qa of air passing through the air conditioner 3 is calculated.

For the temperature Ta,in at the inlet of the air conditioner 3, the following equation (7) is established.

Ta,in=(Q3/Qa)·Tr,out+(Q4/Qa·Ta,out (7)

For the airflow rate Qa of the air passing through the air conditioner, the following equation (8) is established.

Q3+Q4=Qa (8)

From the above equations (7) and (8), the following equation (9) may be determined.

Q4/Qa=(Ta,in−Tr,out)/(Ta,out−Tr,out) (9)

From the above equations (1), (6), and (9), the index A may be determined by the following equation (10).

A=ξ·{(Ta,out−Tr,in)/(Ta,out−Trᵢout)}·{(Ta,in−Ta,out)/(Tr,in−Tr,out)}+η·(Ta,in−Tr,out)/(Ta,out−Tr,out) (10)

The controller 15 controls the airflow rate of air being discharged from the air conditioner 3 by controlling the motor frequency of the blower 4 in the inverter 14a such that the index A is reduced.

The data center 1 may accommodate a plurality of air conditioners 3 and a plurality of racks 6 therein. In this case, the index A may be calculated using the above equation (10) by setting in the above equations in the following manner; the total airflow rate of the air sucked into the racks through the intake ports of the racks, out of cooled air discharged from the outlets of the air conditioners, is set to the airflow rate Q1; the total airflow rate of the air sucked into the racks through the intake ports (the total airflow rate of ejected air directly returning), out of air ejected from the exhaust ports of the racks, is set to the airflow rate Q2; the total airflow rate of the air sucked into the air conditioners through the inlets, out of air ejected from the racks, is set to the airflow rate Q3; the total airflow rate of the air sucked into the air conditioners 3 through the inlets (the total airflow rate of cooled air directly returning), out of cooled air discharged through the outlets of the air conditioners 3, is set to the airflow rate Q4; the mean temperature at the intake ports of the racks is set to the temperature Tr,in; the mean temperature at the exhaust ports of the racks is set to the temperature Tr,out; the mean temperature at the outlets of the air conditioners is set to the temperature Ta,out; and the mean temperature at the inlets of the air conditioners is set to the temperature Ta,in.

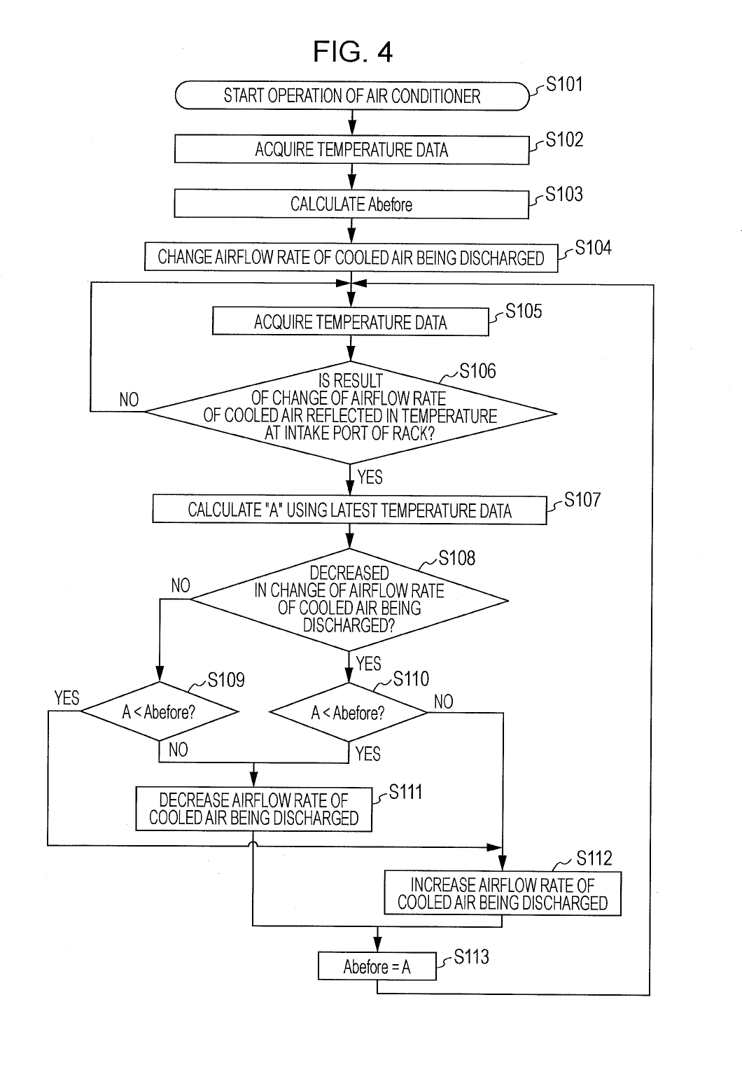

FIG. 4 is a flowchart of a process of a cooling method for use in the cooling system according to the first embodiment.

First, the controller 15 controls the frequencies in the inverters 14a and 14b and starts an operation of the air conditioner 3 (S101).

Then, the controller 15 acquires temperature data detected by the infrared camera 2 and/or the temperature sensor 18 (S102). Examples of the types of temperature data that may be acquired include a temperature at the intake port 83 of the rack 6, a temperature at the exhaust port 84, a temperature at the inlet 81 of the air conditioner 3, and a temperature at the outlet 82.

For example, the controller 15 may acquire temperature data from the infrared camera 2 or the temperature sensor 18 at specific intervals (e.g., every 10 seconds). If the rack 6 has a plurality of intake ports 83, the controller 15 may acquire a temperature at each of the intake ports 83, calculate the mean temperature, the maximum temperature, or the minimum temperature or the like from the acquired temperature, and store the calculated value as the temperature Tr,in at the intake port 83 of the rack 6. Similarly, if the rack 6 has a plurality of exhaust ports 84 and the air conditioner 3 has a plurality of inlets 81 and a plurality of outlets 82, values calculated by the controller 15 may be stored as the temperature Tr,out at each of the exhaust ports 84 of the rack 6, as the temperature Ta,in at each of the inlets 81 of the air conditioner 3, and the temperature Ta,out at each of the outlets 82 of the air conditioner 3.

Then, the controller 15 calculates “A” using the above equation (10) (S103). The controller 15 stores the calculated A as the reference index Abefore.

Then, the controller 15 controls the frequency in the inverter 14a and changes the airflow rate of cooled air being discharged from the air conditioner 3 (S104).

Then, the controller 15 acquires temperature data detected by the infrared camera 2 and/or the temperature sensor 18 (S105). The types of temperature data that may be acquired in S105 are the same as those in S102.

Then, the controller 15 determines whether the change in the airflow rate of cooled air being discharged has been reflected in the temperature at the intake port 83 of the rack 6 (S106). A technique used in the determination is not particularly limited. An example technique used in the determination is described below.

The controller 15 acquires temperature data from the infrared camera 2 or the temperature sensor 18 at specified intervals (e.g., every 10 seconds). When the difference between the latest temperature acquired at specified intervals and its immediately preceding temperature falls within a specific range, the controller 15 determines that the change in the airflow rate of cooled air being discharged has been reflected in the temperature at the intake port 83 of the rack 6 (YES in S106). When that difference is outside the specific range, the controller 15 determines that the change in the airflow rate of cooled air being discharged has not been reflected in the temperature at the intake port 83 of the rack 6 (NO in S106) and acquires temperature data again (S105). Alternatively, for example, when a specific period of time (e.g., 60 seconds) has elapsed, the controller 15 may determine that the change in the airflow rate of cooled air being discharged has been reflected in the temperature at the intake port 83 of the rack 6 (YES in S106).

When determining that the change in the airflow rate of cooled air being discharged has been reflected in the temperature at the intake port 83 (YES in S106), the controller 15 calculates the index A using the latest temperature data (S107).

When the airflow rate of cooled air being discharged from the air conditioner 3 is decreased in S104 (YES in S108) and the index A calculated in S107 is smaller than the reference index Abefore (YES in S110), the controller 15 increases the airflow rate of cooled air being discharged from the air conditioner 3 (S112). This is because the decrease in the airflow rate of cooled air being discharged from the air conditioner 3 in S104 is assumed to contribute to the reduction in the index A. In contrast, when the airflow rate of cooled air being discharged from the air conditioner 3 is decreased in S104 (YES in S108) and the index A calculated in S107 is larger than the reference index Abefore (NO in S110), the controller 15 decreases the airflow rate of cooled air being discharged from the air conditioner 3 (S111). This is because the decrease in the airflow rate of cooled air being discharged from the air conditioner 3 in S104 is assumed to contribute to the increase in the index A.

When the airflow rate of cooled air being discharged from the air conditioner 3 is increased in S104 (NO in S108) and the index A calculated in S107 is smaller than the reference index Abefore (YES in S109), the controller 15 increases the airflow rate of cooled air being discharged from the air conditioner 3 (S112). This is because the increase in the airflow rate of cooled air being discharged from the air conditioner 3 in S104 is assumed to contribute to the reduction in the index A. When the airflow rate of cooled air being discharged from the air conditioner 3 is increased in S104 (NO in S108) and the index A calculated in S107 is larger than the reference index Abefore (NO in S109), the controller 15 decreases the airflow rate of cooled air being discharged from the air conditioner 3 (S111). This is because the increase in the airflow rate of cooled air being discharged from the air conditioner 3 in S104 is assumed to contribute to the increase in the index A.

After S111 or S112, the controller 15 stores the index A as a new reference index Abefore (S113).

After that, S105 to S113 are repeated in the same manner as described above.

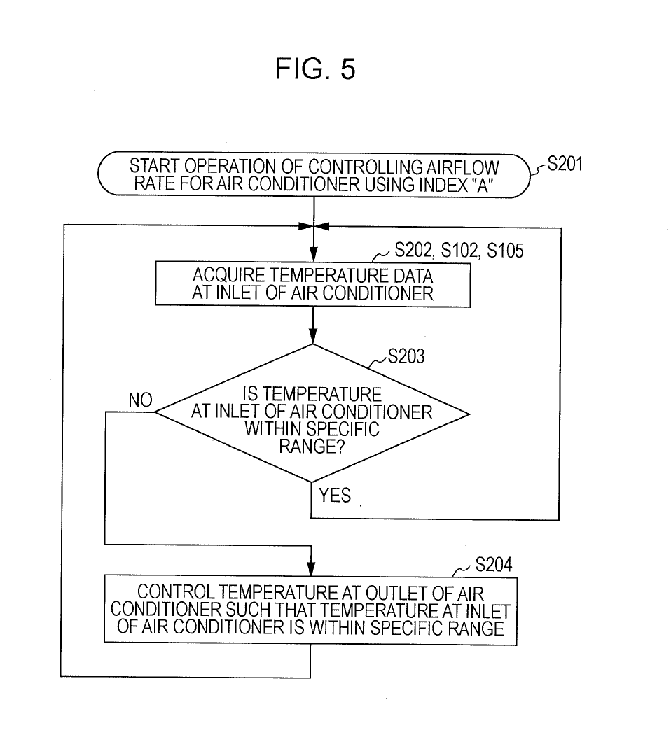

FIG. 5 is a flowchart of a process of a method for controlling a temperature for an air conditioner during an operation of controlling the airflow rate of air from the air conditioner. For the cooling method described with the flowchart of FIG. 4, only the airflow rate of cooled air being discharged from the air conditioner 3 is controlled. However, depending on the amount of heat generated by an electronic device, only controlling the airflow rate of air may be insufficient. In this case, the air conditioner 3 is further controlled in accordance with the flowchart illustrated in FIG. 5.

First, the controller 15 starts an operation of controlling the airflow rate using the index A for the air conditioner, as described using FIG. 4 (S201).

During the operation of controlling the airflow rate, in S102 or S105, the controller 15 acquires temperature data on the inlet of the air conditioner 3 (S202).

Then, the controller 15 determines whether the temperature at the inlet of the air conditioner 3 is within a specific range (S203). When that temperature is within the specific range (YES in S203), the processing returns to S202.

When the temperature at the inlet is above the specific range, it is conceivable that only controlling the airflow rate of air from the air conditioner may be insufficient for cooling in response to heat generated by the electronic device. When the temperature at the inlet is below the specific range, it is conceivable that the amount of heat generated by the electronic device may be small and, even if the airflow rate of air from the air conditioner is decreased, cooling may be excessive. Therefore, when the temperature at the inlet is outside the specific range (NO in S203), the controller 15 performs control such that the temperature at the outlet 82 of the air conditioner 3 is within the specific range by controlling the frequency in the inverter 14b (S204).

A concrete control method used in this stage is not particularly limited. For example, if the temperature at the inlet of the air conditioner 3 is above the specific range, the controller 15 may decrease the temperature at the outlet 82 of the air conditioner 3 by a set value; if the temperature at the inlet of the air conditioner 3 is below the specific range, the controller 15 may increase the temperature at the outlet 82 of the air conditioner 3 by a set value.

After that, S202 to S204 are repeated in the same manner as described above.

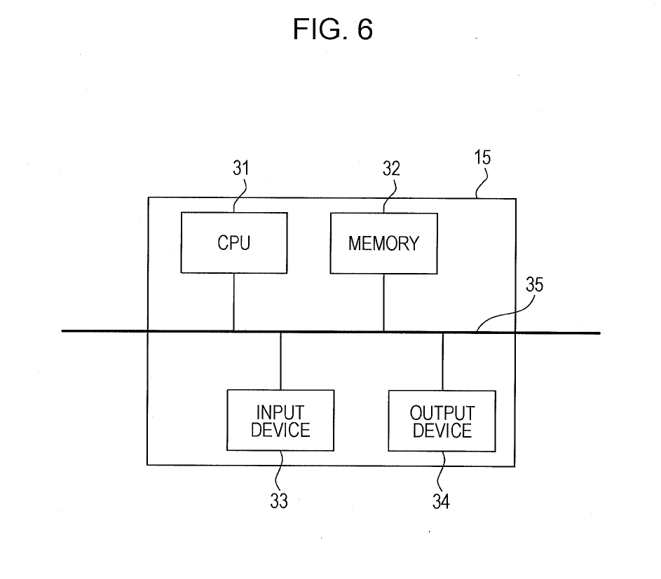

FIG. 6 is a block diagram of the controller 15 of the cooling system according to the first embodiment. The controller 15 includes a central processing unit (CPU) 31, a memory 32, an input device 33, an output device 34, and a bus 35.

The CPU 31 is connected to the memory 32 through the bus 35. Examples of the memory 32 may include a read-only memory (ROM) and a random-access memory (RAM).

The controller 15 is connected to the infrared camera 2, temperature sensor 18, and inverters 14a and 14b. The overall operation of the cooling apparatus in the data center is controlled by the CPU 31. The controller 15 functions as various kinds of control means and various kinds of computing means, such as controlling detection of temperature in the rack 6 and the air conditioner 3 by the infrared camera 2 and the temperature sensor 18, controlling acquisition of temperature detected by the infrared camera 2 and the temperature sensor 18, calculating the index A from the acquired temperature, and controlling the inverters 14a and 14b based on the calculated result in accordance with a specific program.

The memory 32 is employed as a region where a program is allowed to be developed and a region where the CPU 31 is allowed to perform computation works and also as a temporary storage region for temperature data. The memory 32 retains various kinds of data necessary for a program and control executed by the CPU 31 and various kinds of information, such as constants, concerning operations of the infrared camera 2, the temperature sensor 18, and the inverters 14a and 14b.

With the cooling system according to the first embodiment, controlling the airflow rate for the air conditioner such that the index A is reduced decreases the airflow rate of ejected air directly returning to the rack 6 with respect to the airflow rate of air passing through the air conditioner 3 and decreases the airflow rate of cooled air directly returning to the air conditioner 3 with respect to the airflow rate of air passing through the air conditioner 3. Accordingly, the electronic device may be used safely in an energy-saving manner.

### Cooling System According to Second Embodiment

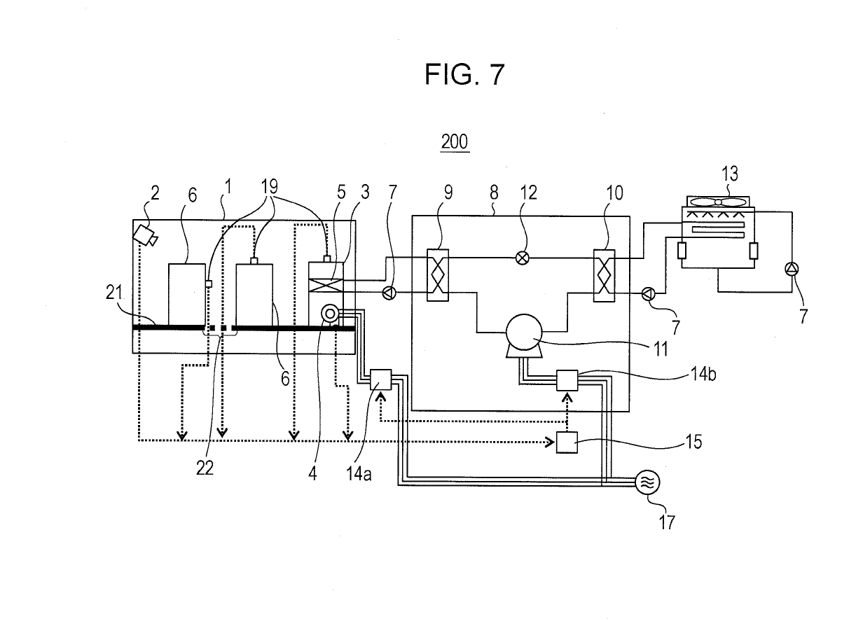

FIG. 7 is a schematic diagram of a cooling system 200 according to a second embodiment. In the description below, the same reference numerals are used as in the cooling system 100 according to the first embodiment for the same configurations, and common description thereof is omitted.

The cooling system 200 according to the second embodiment is a cooling system for cooling an electronic device in a room. The cooling system 200 according to the second embodiment includes one or more racks 6 for housing an electronic device, an air conditioner 3 for cooling the electronic device by sucking air into the room, cooling the sucked air, and discharging the cooled air into the room, an infrared camera 2 for measuring a temperature of the racks 6 and/or the air conditioner 3, and one or more temperature sensors 19 for measuring a temperature of the rack 6 and/or the air conditioner 3. The cooling system 200 according to the second embodiment also includes a controller 15 for acquiring a temperature measured by the infrared camera 2, controlling the air conditioner 3 on the basis of the temperature measured by the infrared camera 2, acquiring a temperature measured by any of the temperature sensors 19, and, when the temperature acquired from the temperature sensor 19 exceeds a specific range, switching control on the air conditioner 3 from control based on a temperature measured by the infrared camera 2 to control based on a temperature measured by the temperature sensor 19.

The air conditioner 3 includes an inlet 81, an outlet 82, a heat exchanger 5, and a blower 4, as in the case of the cooling system according to the first embodiment. The cooling system 200 according to the second embodiment has a mechanism by which heat drawn from air in the data center 1 by the heat exchanger 5 is released to the outside through a refrigerator 8 and the heat exchanger 5, as in the case of the cooling system 100 according to the first embodiment. The description of this mechanism is not repeated here.

The infrared camera 2 obtains an image at a detection target location of the rack 6 and/or the air conditioner 3 and generates information on temperature at that detection target location.

Examples of the detection target location for a temperature measured by the infrared camera 2 include the intake port 83 for a cooled air flow and the exhaust port 84 for ejected air in the rack 6 and the inlet 81 of the air conditioner 3 for sucking air therethrough. The infrared camera 2 may set a wide range for a detection target. Thus even if the number of racks 6 and air conditioners 3 being a target for detecting a temperature is large or the size of each of the racks 6 and air conditioners 3 is large, a temperature of the detection target may be detected by a small number of infrared cameras.

The temperature sensor 19 detects a temperature at a detection target location of the rack 6 and/or air conditioner 3. The temperature sensor 19 may be positioned within a range where the infrared camera 2 may detect temperature, or alternatively, may be outside the range where the infrared camera 2 may detect temperature.

The temperature sensor 19 is provided to judge whether temperature control based on a temperature detected by the infrared camera 2 is proper. When it is judged that temperature control based on a temperature measured by the infrared camera 2 is improper, the controller 15 controls the air conditioner 3 on the basis of temperature data measured by the temperature sensor 19. The temperature sensor 19 may be a thermocouple, for example, and is able to measure a temperature when being thermally coupled to a detection target. The range where the temperature sensor 19 may detect a temperature is narrower than that for the infrared camera 2. Accordingly, the use of a temperature detected by the temperature sensor 19 as a temperature employed as a criterion of determination of control on the air conditioner is not useful from the viewpoint of operation of the cooling system that may sufficiently cool the server housed in the rack 6 while at the same time suppressing energy consumption of the air conditioner 3. However, the temperature sensor 19 may be disposed in the vicinity of a detection target. Therefore, even when an obstacle or human is temporarily present between a detection target and the temperature sensor 19 during measurement by the temperature sensor 19, the temperature may be detected accurately.

The controller 15 retains specific temperature ranges (temperature ranges where a server housed in the rack 6 normally operates) at respective detection target locations for the infrared camera 2. The controller 15 retains specific temperature ranges (temperature ranges indicating that temperature control based on a temperature detected by the infrared camera 2 is proper) at respective detection target locations.

The controller 15 acquires temperature information generated by the infrared camera 2. The temperature information generated by the infrared camera 2 may be information on a temperature at a detection target location by the infrared camera 2, for example. The temperature information generated by the infrared camera 2 may be temperature information generated by the infrared camera 2 for a detection target location and a location other than the detection target location (e.g., image information that contains a pixel value as the temperature). When the temperature information generated by the infrared camera 2 is temperature information for a detection target location and a location other than the detection target location, the controller 15 may acquire temperature information for the detection target location and the location other than the detection target location from the infrared camera 2 and extract temperature information for the detection target location from that acquired temperature information.

As normal cooling means in the data center 1, the controller 15 controls the air conditioner 3 on the basis of information from the infrared camera 2. A concrete method for controlling the air conditioner 3 on the basis of information from the infrared camera 2 is not particularly limited. An example control method is described below. The controller 15 retains information on a temperature range for each detection target location at which the infrared camera 2 may detect a temperature.

The temperature range for each detection target location has been previously stored in the controller 15. When a temperature detected by the infrared camera 2 exceeds the upper limit of the previously stored temperature range, the controller 15 controls the inverter 14a and/or inverter 14b such that the airflow rate of the cooled air flow being discharged through the outlet 82 of the air conditioner 3 is increased and/or the temperature of the cooled air discharged through the outlet 82 of the air conditioner 3 is decreased. For example, when the temperature falls below the lower limit of the previously retained temperature range, the controller 15 controls the inverter 14a and/or inverter 14b such that the airflow rate of cooled air being discharged through the outlet 82 of the air conditioner 3 is decreased and/or the temperature of the cooled air discharged through the outlet 82 of the air conditioner 3 is increased.

The amount of the above-described increase or decrease in the airflow rate of the cooled air flow and/or the amount of the above-described increase or decrease in the temperature of the cooled air flow are determined depending on the size of the data center 1, the amount of heat generated by a server, arrangement of the rack 6 and arrangement of the vent 22 with respect to the air conditioner 3, and the like and may be changed during controlling the air conditioner 3 on the basis of information from the infrared camera 2. The frequency of temperature detections by the infrared camera 2 and the frequency of acquisitions of temperature data by the controller 15 from the infrared camera 2 are not particularly limited.

When a temporary presence of an obstacle or human between the infrared camera 2 and a detection target location of each of the rack 6 and the air conditioner 3 disables the function of temperature detection by the infrared camera 2, the controller 15 switches temperature control on the air conditioner 3 from that using the infrared camera 2 to that using the temperature sensor 19.

Whether the infrared camera 2 may not function is determined by detecting a temperature at a specific location of the air conditioner 3 or rack 6 using the temperature sensor 19 disposed on the air conditioner 3 or rack 6 and judging whether the temperature at that specific location has exceeded a predetermined specific temperature range.

First, a situation where a human is temporarily present between the infrared camera 2 and the rack 6 is discussed. When a human temporarily exists between the infrared camera 2 and the rack 6, the temperature at a detection target location observed by the infrared camera 2 exceeds a temperature range for the detection target location (temperature range where a server housed in the racks 6 normally operates). When the controller 15 acquires the temperature at the detection target location from the infrared camera 2, if the temperature at that detection target location is above the previously stored temperature range, the controller 15 controls the inverter 14a such that the number of revolutions of the motor of the blower 4 disposed in the air conditioner 3 is increased.

At this time, when the airflow rate of sucked air into and the airflow rate of ejected air from the rack 6 are virtually constant and the amount of heat generated by the server housed in the rack 6 remains substantially unchanged, the temperature of ejected air from the rack 6 is substantially the same as or decreases from that before the appearance of the human. Even when the airflow rate of the cooled air flow being discharged from the air conditioner 3 has been increased, the temperature at the detection target location for the infrared camera 2 has not decreased. Therefore, the controller 15 controls the inverter 14a such that the airflow rate of the cooled air flow being discharged from the air conditioner 3 is increased.

When determining that the temperature detected by the temperature sensor 19 at a specific location has exceeded the previously stored specific temperature range, the controller 15 switches temperature control on the air conditioner 3 from temperature control using the infrared camera 2 to temperature control using the temperature sensor 19. This switching may suppress an increase in the airflow rate of cooled air that is discharged from the air conditioner 3 and returns to the inlet 81 of the air conditioner 3 without passing through the rack 6 (surplus volume of air) caused by an increase in the airflow rate of the cooled air flow being discharged from the air conditioner 3. Accordingly, excessive energy consumption may be suppressed.

Another situation where an obstacle is temporarily present between the infrared camera 2 and the rack 6 is discussed. When an obstacle temporarily exists between the infrared camera 2 and the rack 6, the temperature at a detection target location observed by the infrared camera 2 falls below a temperature range for the detection target location (temperature range where a server housed in the racks 6 normally operates). When the controller 15 acquires the temperature at the detection target location from the infrared camera 2, if the temperature at that detection target location is below the previously stored temperature range, the controller 15 controls the inverter 14a such that the number of revolutions of the motor of the blower 4 disposed in the air conditioner 3 is reduced.

At this time, when the air rate of sucked air into and the air rate of ejected air from the rack 6 are virtually constant and the amount of heat generated by the server housed in the rack 6 remains substantially the same, the temperature of ejected air from the rack 6 is substantially the same as or increases from that before the appearance of the obstacle. Even when the airflow rate of the cooled air flow being discharged from the air conditioner 3 has been decreased, the temperature at the detection target location for the infrared camera 2 has not increased. Therefore, the controller 15 controls the inverter 14a such that the airflow rate of the cooled air flow being discharged from the air conditioner 3 is further decreased.

When determining that the temperature detected by the temperature sensor 19 at a specific location has fallen below the previously stored specific temperature range, the controller 15 switches temperature control on the air conditioner 3 from temperature control using the infrared camera 2 to temperature control using the temperature sensor 19. This switching may prevent an actual temperature at a detection target location detected by the infrared camera 2 from exceeding a temperature where the server housed in the rack 6 normally operates.

The above-described temperature control on the air conditioner 3 using the temperature sensor 19 is not particularly limited. For example, when a temperature detected by the temperature sensor 19 exceeds the upper limit of the previously stored temperature range, the controller 15 may control the inverter 14a and/or inverter 14b such that the airflow rate of the cooled air flow being discharged through the outlet 82 of the air conditioner 3 is increased and/or the temperature of the cooled air flow discharged through the outlet 82 of the air conditioner 3 is decreased.

For example, when the temperature detected by the temperature sensor 19 falls below the lower limit of the previously retained temperature range, the controller 15 may control the inverter 14a and/or inverter 14b such that the airflow rate of the cooled air flow being discharged through the outlet 82 of the air conditioner 3 is decreased and/or the temperature of the cooled air discharged through the outlet 82 of the air conditioner 3 is increased. The amount of the increase in the airflow rate of the cooled air flow and/or the amount of the decrease in the temperature of the cooled air flow are determined depending on the size of the data center 1, the amount of heat generated by the server, arrangement of the rack 6 and arrangement of the vent 22 with respect to the air conditioner 3, and the like and may be changed during cooling operation.

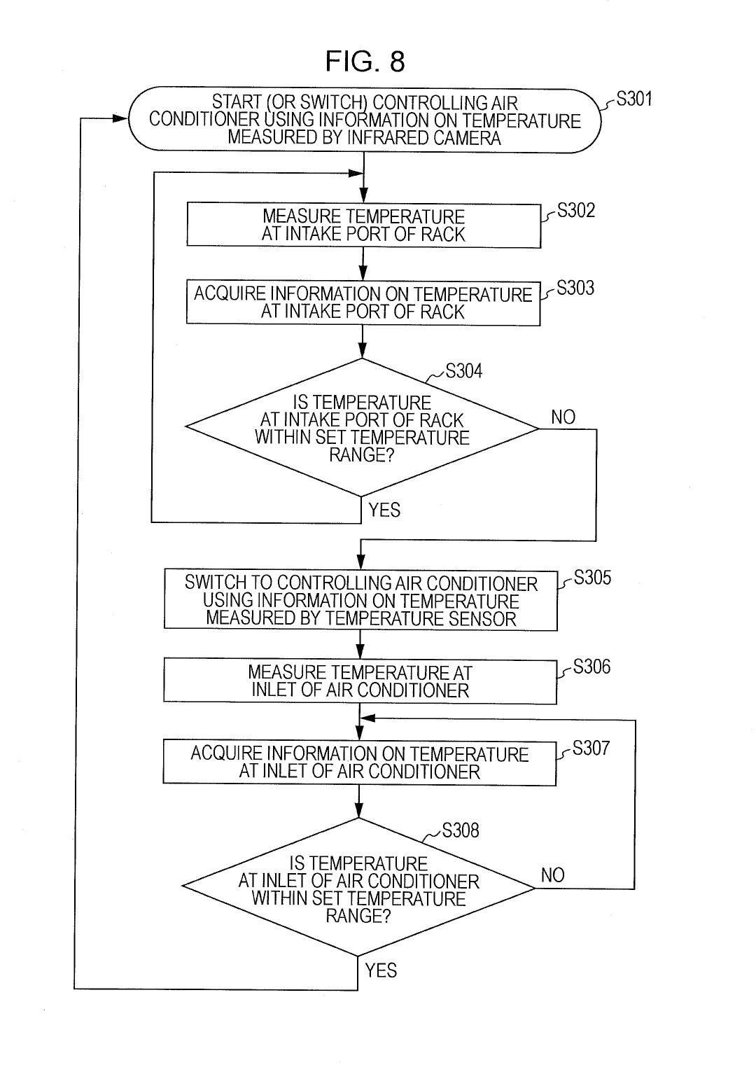

FIG. 8 is a flowchart of a process of an example cooling operation in the cooling system according to the second embodiment.

First, the controller 15 starts an operation of controlling the airflow rate for the air conditioner 3 using temperature information on a temperature at a detection target location measured by the infrared camera 2 (S301). The controller 15 makes the infrared camera 2 measure the temperature at the intake port 83 of the rack 6 (S302). The controller 15 acquires information on the temperature at the intake port 83 of the rack 6 measured by the infrared camera 2 (S303). The controller 15 compares the temperature information for the intake port 83 of the rack 6 measured by the infrared camera 2 against a temperature range for that detection target location stored in the controller 15 and judges whether the measured temperature value at the intake port 83 of the rack 6 is within the temperature range for that detection target location stored in the controller 15 (S304).

When it is judged that the measured temperature value at the intake port 83 of the rack 6 is within the temperature range for that detection target location stored in the controller 15 (YES in S304), the controller 15 carries out S302 and S303 again.

When it is judged that the measured temperature value at the intake port 83 of the rack 6 is outside the temperature range for that detection target location stored in the controller 15 (NO in S304), the controller 15 switches the operation of controlling the airflow rate for the air conditioner 3 from that using information on a temperature measured by the infrared camera 2 to that using information on a temperature measured by the temperature sensor 19 (S305).

The controller 15 makes the temperature sensor 19 measure the temperature at the inlet 81 of the air conditioner 3 (S306). The controller 15 acquires information on the temperature measured by the temperature sensor 19 (S307). The controller 15 compares the temperature information for the inlet 81 of the air conditioner 3 measured by the temperature sensor 19 against a temperature range for that detection target location stored in the controller 15 and judges whether the measured temperature value for the inlet 81 of the air conditioner 3 is within the temperature range for that detection target location stored in the controller 15 (S308).

When it is judged that the measured temperature value at the inlet 81 of the air conditioner 3 is within the temperature range for that detection target location stored in the controller 15 (YES in S308), the controller 15 switches the operation of controlling the airflow rate for the air conditioner 3 from that using information on a temperature measured by the temperature sensor 19 to that using information on a temperature measured by the infrared camera 2 (S301).

When it is judged that the measured temperature value at the inlet 81 of the air conditioner 3 is outside the temperature range for that detection target location stored in the controller 15 (NO in S308), the controller 15 makes the temperature sensor 19 measure the temperature at the inlet 81 of the air conditioner 3 again (S306) and acquires information on the temperature at the inlet 81 of the air conditioner 3 measured by the temperature sensor 19 (S307).

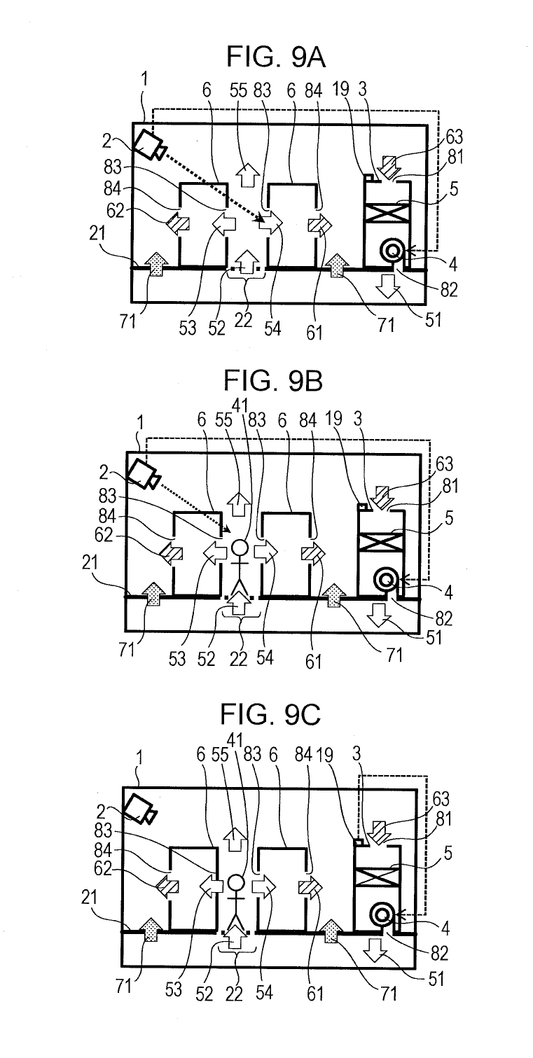

FIGS. 9A to 9C are schematic diagrams of an example of the cooling operation in the cooling system according to the second embodiment. During the cooling operation using the infrared camera 2, the controller 15 controls an airflow rate 51 of air being discharged through the outlet 82 of the air conditioner 3 to cool the server housed in the rack 6 by controlling the inverter frequency of the motor of the blower 4 on the basis of a temperature at the intake port 83 of the rack 6 measured by the infrared camera 2. The temperature sensor 19 is disposed at the inlet 81 of the air conditioner 3 and detects a temperature of air sucked into the air conditioner 3. The controller 15 may retain 27° C.-28.5° C. as a predetermined temperature range for the inlet 81 of the air conditioner 3, for example. When the temperature at the inlet 81 of the air conditioner 3 acquired from the temperature sensor 19 is outside the specific range, the controller 15 switches temperature control on the air conditioner 3 from that using the infrared camera 2 to that using the temperature sensor 19.

FIG. 9A illustrates a state where the air conditioner 3 is operated while the inverter frequency of the motor of the blower 4 is controlled on the basis of a temperature at the intake port 83 of the rack 6 detected by the infrared camera 2. For the present embodiment, the controller 15 (not illustrated) controls the airflow rate 51 of air being discharged through the outlet 82 of the air conditioner 3 on the basis of a temperature at the intake port 83 of the rack 6 detected by the infrared camera 2.

For example, the wind 51 being discharged through the outlet 82 of the air conditioner 3 has a temperature of approximately 20° C. and an airflow rate of approximately 250 m3/min, winds 53 and 54 sucked into the racks 6 through the intake ports 83 have a maximum temperature of approximately 20° C. and an airflow rate of approximately 200 m3/min, wind 71 in a route along which air exits from the outlet 82 of the air conditioner 3, passes through a cable hole or the like formed in the floor 21, and returns directly to the air conditioner 3 without being supplied to an electronic device housed in each of the racks 6 has an airflow rate of approximately 50 m3/min, and ejected air flows 61 and 62 from the racks 6 has a temperature of approximately 30° C. The ejected air flows 61 and 62 are mixed with the wind 71 in the route along which air exits from the outlet 82 of the air conditioner 3, passes through a cable hole or the like formed in the floor 21, and returns directly to the air conditioner 3 and wind 55 in a route along which, of wind 52 in a route passing through the vent 22, air directly returns to the air conditioner 3 without being sucked into the racks 6. Wind 63 to the inlet 81 of the air conditioner 3 is air in which the winds 71 and 55 in the route along which air exits from the outlet 82 of the air conditioner 3 and returns directly to the air conditioner 3 and the ejected air flows 61 and 62 from the racks 6 are mixed and has a temperature of approximately 28° C., for example.

FIG. 9B illustrates a state where a creature 41, such as a human, having a temperature exceeding 20° C., which is a target temperature at the intake port 83 of each of the racks 6 is present between the infrared camera 2 and the intake port 83 of the rack 6 and the air conditioner 3 is operated while the inverter frequency of the motor of the blower 4 is controlled on the basis of the temperature at the intake port 83 of the rack 6 detected by the infrared camera 2.

The infrared camera 2 detects a temperature of the creature 41 as a temperature at the intake port 83 of the rack 6. The controller 15 acquires the temperature detected by the infrared camera 2. The controller 15 (not illustrated) controls the inverter 14a (not illustrated) on the basis of the acquired temperature of the creature such that the airflow rate of the wind 51 at the outlet 82 of the air conditioner 3 is increased.

When the infrared camera 2 detects approximately 36° C. being the temperature of the creature 41 as the temperature at the intake port 83 of the rack 6, the controller 15 controls the inverter 14a on the basis of the detected temperature such that the airflow rate of the wind 51 being discharged through the outlet 82 of the air conditioner 3 increases from approximately 250 m3/min to approximately 350 m3/min.

At this time, the airflow rate of each of the cooled air flows 53 and 54 sucked into the racks 6 through the intake ports 83 remains at approximately 200 m3/min, whereas the airflow rate of the wind 71 in the route along which air exits through the outlet 82 of the air conditioner 3, passes through a cable hole or the like formed in the floor 21, returns directly to the air conditioner 3 without being supplied to the electronic device housed in each of the racks 6 increases from approximately 50 m3/min to approximately 150 m3/min. The temperature of the ejected air flows 61 and 62 from the rack 6 remains at approximately 30° C. The temperature of the wind 63 passing through the inlet 81 of the air conditioner 3 decreases to approximately 25.7° C., for example. When determining that the temperature at the inlet 81 of the air conditioner 3 has fallen below 27° C., the controller 15 switches temperature control on the air conditioner 3 from that using the infrared camera 2 to that using the temperature sensor 19. This control switching may reduce the airflow rate of the wind 71 in the route along which air exits through the outlet 82 of the air conditioner 3 and returns directly to the air conditioner 3 without being supplied to the electronic device housed in the rack 6 and thus suppress excessive energy consumption by the air conditioner 3.

FIG. 9C illustrates a state where the airflow rate of the cooled air flow at the outlet 82 of the air conditioner 3 is controlled on the basis of the temperature at the inlet 81 of the air conditioner 3 measured by the temperature sensor 19.

The controller 15 controls the inverter 14a on the basis of the temperature at the inlet 81 of the air conditioner 3 such that the airflow rate at the outlet 82 of the air conditioner 3 decreases from approximately 350 m3/min to approximately 285 m3/min. With this decrease in the airflow rate at the outlet 82 of the air conditioner 3, the airflow rate of the wind 71 in the route along which air exits through the outlet 82 of the air conditioner 3, passes through the cable hole or the like formed in the floor 21, and returns directly to the air conditioner 3 without being supplied to the electronic device housed in the rack 6 decreases from approximately 150 m3/min to approximately 85 m3/min, for example. The winds 53 and 54 sucked into the racks 6 through the intake ports 83 remain at a temperature of approximately 20° C. and an airflow rate of approximately 200 m3/min. In this way, the servers in the racks 6 may be operated while at the same time excessive energy consumption by the air conditioner 3 is suppressed.

When determining that the temperature at the intake port 83 of the air conditioner 3 detected by the temperature sensor 19 is at or above 27° C., which is the lower limit of the previously stored temperature range, the controller 15 switches control on the air conditioner 3 from that using the temperature sensor 19 to that using the infrared camera 2. Because a temperature detection range of the infrared camera 2 is wider than that of the temperature sensor 19, the control on the air conditioner 3 on the basis of a temperature detected by the infrared camera 2 enables the air conditioner 3 to be controlled in greater detail responsive to heat locally generated by the server in the rack 6. The lower limit of the temperature range is not limited to 27° C.; it may be set to any value.

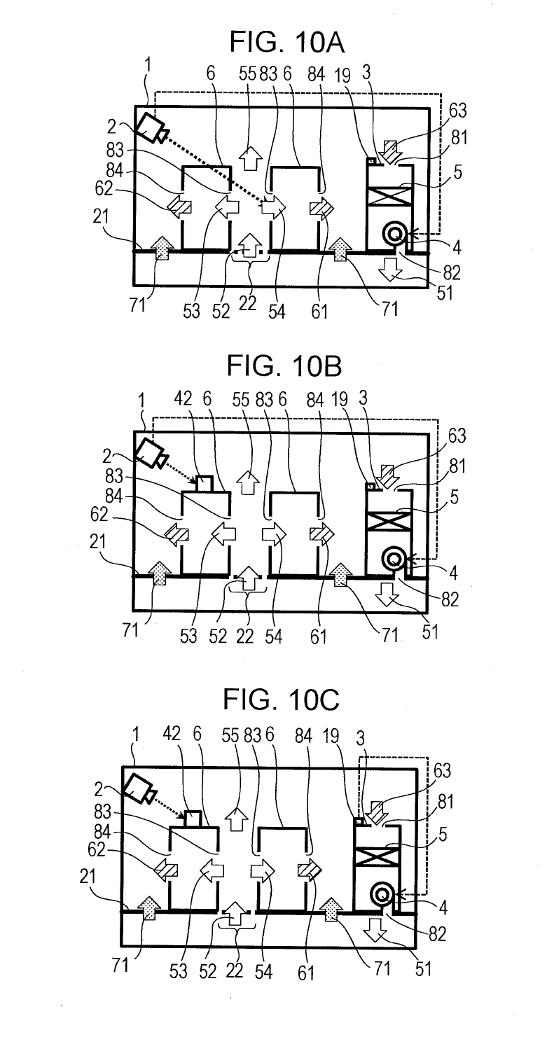

FIGS. 10A to 10C are schematic diagrams of another example of the cooling operation in the cooling system according to the second embodiment.

FIG. 10A illustrates a state where the air conditioner 3 is operated while the inverter frequency of the motor of the blower 4 is controlled on the basis of a temperature at the intake port 83 of the rack 6 detected by the infrared camera 2. For example, the wind 51 being discharged through the outlet 82 of the air conditioner 3 has a temperature of approximately 20° C. and an airflow rate of approximately 250 m3/min, the winds 53 and 54 sucked into the racks 6 through the intake ports 83 of the rack 6 have a maximum temperature of approximately 20° C. and an airflow rate of approximately 200 m3/min, the wind 71 in the route along which air exits from the outlet 82 of the air conditioner 3, passes through a cable hole or the like formed in the floor 21, and returns directly to the air conditioner 3 without being supplied to an electronic device housed in each of the racks 6 has an airflow rate of approximately 50 m3/min, and the ejected air flows 61 and 62 from the racks 6 have a temperature of approximately 30° C.

The ejected air flows 61 and 62 are mixed with the wind 71 in the route along which air exits from the outlet 82 of the air conditioner 3, passes through a cable hole or the like formed in the floor 21, and returns directly to the air conditioner 3 and the wind 55 in which, of wind 52 in a route passing through the vent 22, air directly returns to the air conditioner 3 without being supplied to the racks 6. The wind 63 passing through the inlet 81 of the air conditioner 3 is air in which the winds 71 and 55 in the route along which air exits from the outlet 82 of the air conditioner 3 and returns directly to the air conditioner 3 are mixed with the ejected air flows 61 and 62 from the racks 6 and has a temperature of approximately 28° C., for example. The total amount of heat by the servers in the racks 6 is approximately 36.8 kW, for example.

FIG. 10B illustrates a state where an obstacle 42 having a temperature below 20° C., which is a target temperature at the intake port 83 of each of the racks 6, is present between the infrared camera 2 and the intake port 83 of the rack 6 and the air conditioner 3 is operated while the inverter frequency of the motor of the blower 4 is controlled on the basis of the temperature at the intake port 83 of the rack 6 detected by the infrared camera 2.

The infrared camera 2 detects a temperature of the obstacle 42 as a temperature at the intake port 83 of the rack 6. The controller 15 acquires the temperature detected by the infrared camera 2. The controller 15 (not illustrated) controls the inverter 14a (not illustrated) on the basis of the acquired temperature of the obstacle 42 such that the airflow rate at the outlet 82 of the air conditioner 3 is decreased.

Also, in a state where the infrared camera 2 detects approximately 20° C. being the temperature of the obstacle 42 as the temperature at the intake port 83 of the rack 6, when the total amount of heat generated by the servers in the racks 6 rises from approximately 36.8 kW to approximately 46 kW, for example, the controller 15 continues controlling the inverter 14a such that the airflow rate of the wind 51 being discharged through the outlet 82 of the air conditioner 3 is 250 m3/min, irrespective of the amount of heat generated by the servers housed in the racks 6.

In a state where the infrared camera 2 detects approximately 20° C. being the temperature of the obstacle 42 as the temperature of the intake port 83 at the rack 6 and where the amount of heat generated by the servers in the racks 6 rises, if the data center 1 continues being used, the temperature at each of the intake ports 83 and exhaust ports 84 of the racks 6 and inlet 81 of the air conditioner 3 rises.

For this example cooling operation, when determining that the temperature measured by the temperature sensor 19 has exceeded the upper limit 28.5° C. of the predetermined temperature range for the inlet 81 of the air conditioner 3, the controller 15 switches control on the air conditioner 3 from that using the infrared camera 2 to that using the temperature sensor 19. This control switching may prevent a failure of the server or loss of data stored in the server caused by a high temperature (e.g., 40° C. or above) of the room of the data center 1 resulting from a temperature rise in the server in the rack 6. The upper limit of the temperature range is not restricted to 28.5° C.; it may be set to any value.

FIG. 10C illustrates a state where the airflow rate of the cooled air flow at the outlet 82 of the air conditioner 3 is controlled on the basis of a temperature at the inlet 81 of the air conditioner 3 measured by the temperature sensor 19.

The controller 15 controls the inverter 14b on the basis of the temperature at the inlet 81 of the air conditioner 3 such that the airflow rate at the outlet 82 of the air conditioner 3 increases from approximately 250 m3/min to approximately 2919 m3/min. The increase in the airflow rate at the outlet 82 of the air conditioner 3 leads to a decrease in the temperatures at the intake port 83 and exhaust port 84 of the rack 6 and at the inlet 81 of the air conditioner 3. The server in the rack 6 is controllable at temperatures at which a failure of the server and loss of data stored in the server may be prevented for a short period of time.

The cooling system according to the second embodiment may further include a monitor and/or an alarm (not illustrated). The monitor and/or alarm are connected to the controller 15. When a temperature measured by the temperature sensor 19 falls outside a temperature range of the temperature sensor 19 for a detection target region stored in the controller 15, the controller 15 outputs a warning indication to the monitor and/or issues an alarm. The obstacle 42 present between the infrared camera 2 and the intake port 83 of the rack 6 being a detection target by the infrared camera 2 does not move by itself. An administrator of the data center 1 who noticed the warning indication or the alarm may move the obstacle 42 present between the infrared camera 2 and the intake port 83 of the rack 6 being a detection target by the infrared camera 2 to avoid a failure of the server and loss of data stored in the server.

When determining that the temperature at the inlet 81 of the air conditioner 3 measured by the temperature sensor 19 is at or below the upper limit 28.5° C. of the predetermined temperature range, the controller 15 switches temperature control on the air conditioner 3 from that using the temperature sensor 19 to that using the infrared camera 2. Because the temperature detection range of the infrared camera 2 is wider than that of the temperature sensor 19, the control on the air conditioner 3 on the basis of a temperature detected by the infrared camera 2 enables the air conditioner 3 to be controlled in greater detail responsive to heat locally generated by the server in the rack 6.

A variation of the cooling system according to the second embodiment may control a temperature of wind discharged through the outlet 82 of the air conditioner 3, in place of an airflow rate thereof. During a cooling operation using the infrared camera 2, the controller 15 controls a temperature of the cooled air flow discharged through the outlet 82 of the air conditioner 3 by controlling the motor frequency of the compressor 11 in the inverter 14b, in place of controlling the inverter frequency of the motor of the blower 4, on the basis of a temperature at the intake port 83 of the rack 6 detected by the infrared camera 2 to cool the server housed in the rack 6.

The temperature sensor 19 is disposed at the inlet 81 of the air conditioner 3 and detects a temperature of air sucked to the air conditioner 3. The controller 15 retains 27° C. to 28.5° C., for example, as the predetermined temperature range for the inlet 81 of the air conditioner 3. When the temperature at the inlet 81 of the air conditioner 3 acquired from the temperature sensor 19 is outside the specific range, the controller 15 switches temperature control on the air conditioner 3 from that using the infrared camera 2 to that using the temperature sensor 19.

Example temperatures and airflow rates in the data center 1 when the creature 41 having a temperature exceeding 20° C., which is a target temperature at the intake port 83 of the rack 6, is present between the infrared camera 2 and the intake port 83 of the rack 6, as illustrated in FIG. 9B, in a state where the air conditioner 3 is operated while the inverter frequency of the motor of the blower 4 is controlled on the basis of a temperature at the intake port 83 of the rack 6 detected by the infrared camera 2, as illustrated in FIG. 9A, are described below.

The infrared camera 2 detects a temperature of the creature 41 as a temperature at the intake port 83 of the rack 6. The controller 15 acquires the temperature detected by the infrared camera 2. The controller 15 (not illustrated) controls the inverter 14b (not illustrated) on the basis of the acquired temperature of the creature such that the temperature of the wind 51 at the outlet 82 of the air conditioner 3 is decreased.

When the infrared camera 2 detects approximately 36° C. being the temperature of the creature 41 as the temperature of the intake port 83 of the rack 6, the controller 15 controls the inverter 14b on the basis of the detected temperature such that the temperature of the wind 51 discharged through the 82 of the air conditioner 3 decreases from approximately 20° C. to approximately 15° C., for example. At this time, the airflow rate of each of the cooled air flows 53 and 54 sucked into the intake ports 83 of the racks 6 remains at approximately 200 m3/min, and its temperature decreases to approximately 15° C.

The airflow rate of the wind 71 in a route along which air exits from the outlet 82 of the air conditioner 3, passes through a cable hole or the like formed in the floor 21, and returns directly to the air conditioner 3 without being supplied to an electronic device housed in each of the racks 6 remains at approximately 250 m3/min and its temperature decreases from approximately 20° C. to approximately 15° C. The temperature of each of the ejected air flows 61 and 62 from the rack 6 decreases from approximately 30° C. to approximately 25° C. The temperature of the wind 63 passing through the inlet 81 of the air conditioner 3 decreases to approximately 23° C. When determining that the temperature at the inlet 81 of the air conditioner 3 has fallen below 27° C., the controller 15 switches temperature control on the air conditioner 3 from that using the infrared camera 2 to that using the temperature sensor 19. This control switching may raise the temperature of the cooled air flows 53 and 54 sucked into the rack 6 through the intake port 83 and thus suppress excessive energy consumption by the air conditioner 3.

Example temperatures and airflow rates in the data center 1 when the cooled air flow discharged through the outlet 82 of the air conditioner 3 is controlled on the basis of a temperature at the inlet 81 of the air conditioner 3 measured by the temperature sensor 19, as illustrated in FIG. 9C, are described below. The controller 15 controls the inverter 14b on the basis of a temperature at the inlet 81 of the air conditioner 3 such that the temperature of the wind 51 at the outlet 82 of the air conditioner 3 increases from approximately 15° C. to approximately 19° C. In response to the rise in the cooled air flow discharged through the outlet 82 of the air conditioner 3, the temperature of each of the winds 53 and 54 sucked into the racks 6 through the intake ports 83 increases from approximately 15° C. to approximately 19° C., and its airflow rate remains at approximately 200 m3/min.

The temperature of the wind 71 in the route along which air exits from the outlet 82 of the air conditioner 3, passes through a cable hole or the like formed in the floor 21, and returns directly to the air conditioner 3 without being supplied to an electronic device housed in each of the racks 6 increases from approximately 15° C. to approximately 19° C., and its airflow rate remains at approximately 50 m3/min. The temperature of each of the ejected air flows 61 and 62 from the rack 6 increases from approximately 25° C. to approximately 29° C. The temperature of the wind 63 passing through the inlet 81 of the air conditioner 3 increases from approximately 23° C. to approximately 27° C. In this way, the server in the rack 6 may be operated while at the same time excessive energy consumption by the air conditioner 3 is suppressed.

When determining that the temperature at the inlet 81 of the air conditioner 3 detected by the temperature sensor 19 is at or above 27° C., which is the lower limit of the predetermined temperature range, the controller 15 switches temperature control on the air conditioner 3 from that using the temperature sensor 19 to that using the infrared camera 2. Because the temperature detection range of the infrared camera 2 is wider than that of the temperature sensor 19, the control on the air conditioner 3 on the basis of a temperature detected by the infrared camera 2 enables the air conditioner 3 to be controlled in greater detail responsive to heat locally generated by the server in the rack 6.

In the cooling system 200 according to the above-described second embodiment, the detection target region of the infrared camera 2 is the intake port 83 of the rack 6. However, that detection target region is not limited to the intake port 83. For example, it may be the exhaust port 84 of the rack 6. Also, the detection target region of the temperature sensor 19 is not limited to the inlet 81 of the air conditioner 3. For example, it may be the intake port 83 and/or exhaust port 84 of the rack 6, and it may also be a specified location inside the rack 6. In these cases, failures in an electronic device caused by heat may be prevented while at the same time excessive energy consumption by the air conditioner 3 is suppressed.

In the cooling system 200 according to the above-described second embodiment, switching control on the air conditioner 3 from that based on a temperature measured by the infrared camera 2 to that based on a temperature measured by the temperature sensor 19 is determined by judgment whether a temperature measured by the temperature sensor 19 exceeds a predetermined temperature range. However, the determination of switching in the disclosed technique is not limited to the above-described process.

For example, the cooling system 200 may include detection means for detecting a running status of the cooling system, in addition to the temperature sensor 19, to allow the running status to be used in the above-described determination. Examples of the detection means may include an airflow meter for measuring an airflow rate at the inlet 81 and/or the outlet 82 of the air conditioner 3 and a measuring instrument for measuring power consumption necessary for actuating the blower 4 and/or the heat exchanger 5.

Specifically, an airflow meter (not illustrated) may be disposed at the inlet 81 and/or the outlet 82 of the air conditioner 3, the controller 15 may acquire information on an airflow rate of sucked air or ejected air measured by the airflow meter, and judgment whether the acquired information on the airflow rate exceeds a range indicated by information on an airflow rate for the location where the airflow meter is disposed stored in the controller 15 may be used in the above-described determination.

Alternatively, a measuring instrument (not illustrated) for measuring power consumption necessary for actuating the blower 4 and/or the heat exchanger 5 may be provided, the controller 15 may acquire information on power consumption measured by the measuring instrument, and judgment whether the acquired information on the power consumption exceeds a range indicated by information on power consumption stored in the controller 15 may be used in the above-described determination.

A cooling system in the disclosure is not limited to the cooling system for cooling a server disposed in a data center described in the first and second embodiments. The cooling system in the disclosure encompasses cooling systems for cooling any kind of a heating element, such as an electronic device disposed in a room.

The present invention is not limited to the above-described embodiments. A plurality of embodiments may be combined as long as a contradiction does not arise. The above-described embodiments are merely examples. Anything having substantially the same configuration as that of the technical idea described in claims of the present invention is encompassed in the technical scope of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A cooling system for cooling an electronic device housed in a rack disposed in a room in which an air conditioner is disposed, the air conditioner including an inlet and an outlet and being configured to suck air through the inlet, cool the sucked air, and discharge the cooled air through the outlet, the rack including an intake port and an exhaust port and being configured to suck the cooled air through the intake port and eject the sucked air through the exhaust port, the cooling system comprising:
a control unit configured to acquire a temperature at least one of the intake port and the exhaust port of the rack and the inlet and the outlet of the air conditioner from a temperature measuring instrument for measuring the temperature, to calculate an index concerning an airflow rate of each of the ejected air and the cooled air directly returning, and to perform control on an airflow rate of the cooled air being discharged from the air conditioner on the basis of the calculated result.

2. The cooling system according to claim 1, wherein
the air conditioner further includes a motor and an inverter, the motor being configured to control the airflow rate of the cooled air being discharged through the outlet, the inverter being connected to the motor, and wherein
the airflow rate of the cooled air being discharged from the air conditioner is controlled by control on a motor frequency in the inverter.

3. The cooling system according to claim 1, wherein
the index is calculated by the following expression:
A=ξ·{(Ta,out−Tr,in)/(Ta,out−Tr,out)}·{(Ta,in−Ta,out)/(Tr,in−Tr,out)}+η·(Ta,in−Tr,out)/(Ta,out−Tr,out)
where A is the index concerning the airflow rate of each of the ejected air and the cooled air directly returning, Tr,in is a mean temperature at a rack sucking section, Tr,out is a mean temperature at a rack ejecting section, Ta,out is a temperature of the cooled air being discharged from the air conditioner, Ta,in is a temperature of the air being sucked into the air conditioner, ξ and η are weighting factors.

4. The cooling system according to claim 1, wherein
the control on the airflow rate of the cooled air being discharged from the air conditioner includes changing the airflow rate of the cooled air being discharged from the air conditioner, and the control unit is configured to:
change the airflow rate of the cooled air being discharged and then calculate the index;
judge whether the index is increased or decreased after the airflow rate of the cooled air is changed;
increase the airflow rate of the cooled air being discharged when the airflow rate of the cooled air being discharged is decreased and the index is increased or when the airflow rate of the cooled air being discharged is increased and the index is decreased; and
decrease the airflow rate of the cooled air when the airflow rate of the cooled air being discharged is decreased and the index is decreased or when the airflow rate of the cooled air being discharged is increased and the index is increased.

5. The cooling system according to claim 4, wherein
the control unit is configured to, after changing the airflow rate of the cooled air being discharged, wait until the change of the airflow rate of the cooled air being discharged is reflected in temperatures at the intake port and the exhaust port of the rack and at the inlet and the outlet of the air conditioner.

6. The cooling system according to claim 1, wherein
the control unit is configured to perform control on a temperature of the cooled air being discharged in response to at least one of temperatures at the intake port and the exhaust port of the rack and at the inlet and the outlet of the air conditioner.

7. The cooling system according to claim 6, wherein
the control on the temperature of the cooled air being discharged is performed such that, when a measured temperature at the inlet of the air conditioner exceeded a specific range, the temperature falls within the specific range.

8. A cooling method for cooling an electronic device housed in a rack disposed in a room using an air conditioner, the air conditioner including an inlet that allows air to be sucked there through and an outlet that allows cooled air to be discharged there through and being configured to cool the air sucked through the inlet, the rack including an intake port that allows the cooled air to be sucked there through and an exhaust port, the cooling method comprising:
measuring temperatures at least one of the intake port and the exhaust port of the rack and at the inlet and the outlet of the air conditioner; and
calculating an index concerning an airflow rate of each of the ejected air and the cooled air directly returning and controlling an airflow rate of the cooled air being discharged on the basis of the calculated result.

9. A cooling system for cooling an electronic device disposed in a room, the cooling system comprising:
a rack configured to house the electronic device;
an air conditioner configured to suck air in the room, cool the sucked air, and discharge the cooled air into the room to cool the electronic device housed in the rack;
an infrared camera configured to measure a temperature of the rack and/or the air conditioner;
a temperature sensor configured to measure a temperature of the rack and/or the air conditioner; and
a control unit configured to acquire the temperatures measured by the infrared camera and the temperature sensor and to switch control on the air conditioner from control based on the temperature measured by the infrared camera to control based on the temperature measured by the temperature sensor.

10. The cooling system according to claim 9, wherein
the control unit is configured to, when the temperature acquired from the temperature sensor exceeds a specific range, switch control on the air conditioner from the control based on the temperature measured by the infrared camera to the control based on the temperature measured by the temperature sensor.

11. The cooling system according to claim 9, wherein
the control unit includes detection means for detecting a running status of the cooling system.

12. The cooling system according to claim 10, wherein
the control unit is configured to, when the temperature acquired from the temperature sensor falls within the specific range after the control on the air conditioner is switched to the control based on the temperature measured by the temperature sensor, switch the control on the air conditioner from the control based on the temperature measured by the temperature sensor to the control based on the temperature measured by the infrared camera.

13. The cooling system according to claim 9, wherein
the temperature sensor is nearer to the rack and/or the air conditioner than the infrared camera.

14. A cooling method for cooling an electronic device housed in a rack in a room using an air conditioner, the cooling method comprising:
measuring a temperature of the rack and/or the air conditioner by an infrared camera;
measuring a temperature of the rack and/or the air conditioner by a temperature sensor disposed nearer to the rack and/or the air conditioner than the infrared camera;
acquiring the temperature measured by the infrared camera;
acquiring the temperature measured by the temperature sensor; and
switching control on the air conditioner from control based on the temperature measured by the infrared camera to control based on the temperature measured by the temperature sensor.
